(19) United States
(12) Patent Application Publication
(10) Pub. No.: US 2015/0171028 A1
(43) Pub. Date: Jun. 18, 2015

(54) SEMICONDUCTOR PACKAGE AND METHOD OF FABRICATING THE SAME

(71) Applicants: CHAJEA JO, Incheon (KR); Taeje CHO, Gyeonggi-do (KR); YUNHYEOK IM, Gyeonggi-do (KR)

(72) Inventors: CHAJEA JO, Incheon (KR); Taeje CHO, Gyeonggi-do (KR); YUNHYEOK IM, Gyeonggi-do (KR)

(21) Appl. No.: 14/492,556

(22) Filed: Sep. 22, 2014

(30) Foreign Application Priority Data
Dec. 17, 2013 (KR) 10-2013-0157323

(51) Int. Cl. H01L 23/00; H01L 21/78; H01L 21/56; H01L 21/52; H01L 23/31; H01L 23/36

(52) U.S. Cl. CPC H01L 23/562; H01L 23/3121; H01L 23/36; H01L 21/565; H01L 21/52; H01L 21/78; H01L 21/561

(57) ABSTRACT

A semiconductor package is provided. At least one semiconductor chip is mounted on a package substrate. A mold layer covers the at least one semiconductor chip. The mold layer exposes a portion of a top surface of an uppermost semiconductor chip of the at least one semiconductor chip.

### CROSS-REFERENCE TO RELATED APPLICATION

This application claims priority under 35 U.S.C. §119 to Korean Patent Application No, 10-2013-0157323, filed on Dec. 17, 2013, in the Korean Intellectual Property Office, the disclosure of which is incorporated by reference herein in its entirety.

### TECHNICAL FIELD

The inventive concepts relate to semiconductor packages and methods of fabricating the same.

### DISCUSSION OF RELATED ART

Electronic devices include various system-on-chip (SoC) devices to reduce weight and secure high performance.

SoC devices may be implemented using various package technologies. As the performance of SoC devices increases, more heat is generated from the devices, and thus the performance may be degraded.

### SUMMARY

According to an exemplary embodiment of the present invention, a semiconductor package is provided. At least one semiconductor chip is mounted on a package substrate. A mold layer covers the at least one semiconductor chip. The mold layer exposes a portion of a top surface of an uppermost semiconductor chip of the at least one semiconductor chip.

According to an exemplary embodiment of the present inventive concept, a method of fabricating a semiconductor package is provided. At least one semiconductor chip is mounted on a package substrate. The at least one semiconductor chip and the package substrate are covered with a mold frame. A mold resin solution is supplied into an inner space defined by the mold frame, the at least one semiconductor chip and the package substrate. The mold resin solution is hardened to form a mold layer. The package substrate and the semiconductor chip are curved before the supplying of the mold resin solution.

### BRIEF DESCRIPTION OF THE DRAWINGS

These and other features of the inventive concept will become more apparent by describing in detail exemplary embodiments thereof with reference to the accompanying drawings of which:

FIG. 1 is a layout diagram showing a semiconductor package according to an exemplary embodiment of the inventive concept;

FIGS. 2A and 2B are cross-sectional views taken along line I-I′ of FIG. 1;

FIG. 2C is a perspective view of a semiconductor package of FIG. 2A;

FIG. 3 is an enlarged view of a portion ‘P1’ of FIG. 2A;

FIGS. 4A and 4B are enlarged views of a portion ‘P2’ of FIG. 2A;

FIG. 5 is a cross-sectional view showing the semiconductor package of FIG. 2A or 2B mounted on a motherboard;

FIGS. 6A, 6B and 7 to 10 are cross-sectional views showing a method of fabricating the semiconductor package of FIG. 2A or 2B;

FIGS. 11A and 11B are cross-sectional views showing a modified, exemplary embodiment of the semiconductor package of FIG. 2A;

FIG. 12 is a layout diagram showing a semiconductor package according to an exemplary embodiment of the inventive concept;

FIG. 13A is a cross-sectional view taken along line I-I′ of FIG. 12;

FIGS. 13B and 15 are cross-sectional views taken along line II-II′ of FIG. 12;

FIG. 14 is a perspective view showing semiconductor packages of FIGS. 13A and 13B;

FIGS. 16A and 16B are enlarged views of a portion ‘P2’ of FIG. 13B;

FIGS. 17 to 19 are cross-sectional views showing a method of fabricating the semiconductor packages of FIGS. 13B and 15;

FIGS. 20A and 20B are cross-sectional views showing a modified, exemplary embodiment of the semiconductor package of FIG. 13B;

FIG. 21 is a layout diagram showing a semiconductor package according to an exemplary embodiment of the inventive concept;

FIG. 22 is a cross-sectional view taken along line I-I′ of FIG. 21;

FIGS. 23 and 24 are cross-sectional views showing a method of fabricating the semiconductor package of FIG. 22;

FIGS. 25 and 26 are cross-sectional views showing semiconductor packages according to an exemplary embodiment of the inventive concept;

FIG. 27 is a schematic diagram showing an exemplary package module including a semiconductor package according to an exemplary embodiment of the inventive concept;

FIG. 28 is a schematic block diagram showing an exemplary electronic system including a semiconductor package according to an exemplary embodiment of the inventive concept; and

FIG. 29 is a schematic block diagram showing an exemplary memory card including a semiconductor package according to an exemplary embodiment of the inventive concept.

### DETAILED DESCRIPTION OF EXEMPLARY EMBODIMENTS

Exemplary embodiments of the inventive concept will be described below in detail with reference to the accompanying drawings. However, the inventive concept may be embodied in different forms and should not be construed as limited to the embodiments set forth herein. In the drawings, the thickness of layers and regions may be exaggerated for clarity. It will also be understood that when an element is referred to as being “on” another element or substrate, it may be directly on the other element or substrate, or intervening layers may also be present. It will also be understood that when an element is referred to as being “coupled to” or “connected to” another element, it may be directly coupled to or connected to the other element, or intervening elements may also be present. Like reference numerals may refer to the like elements throughout the specification and drawings.

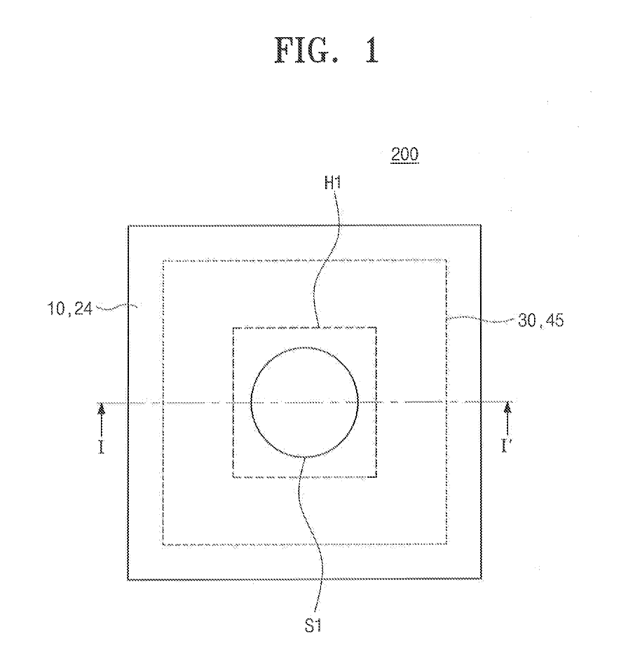

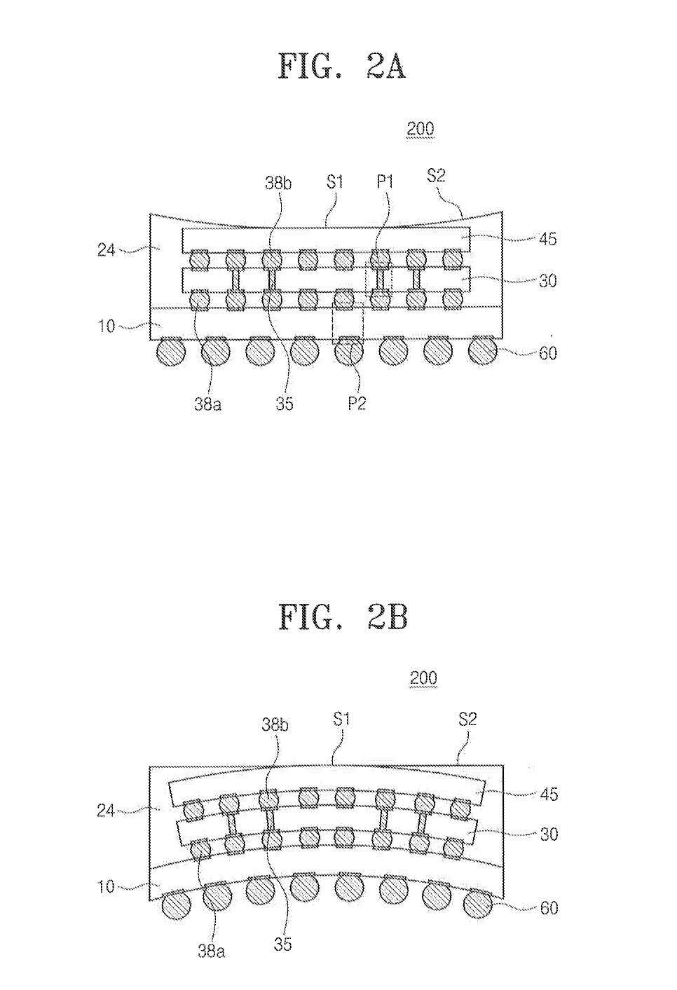

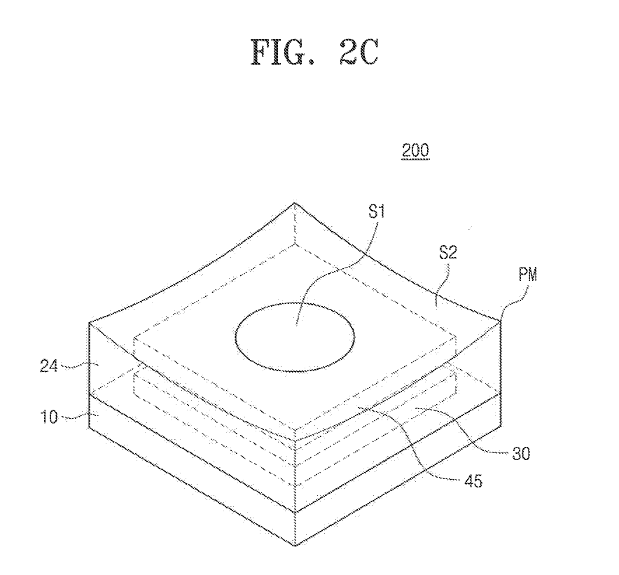

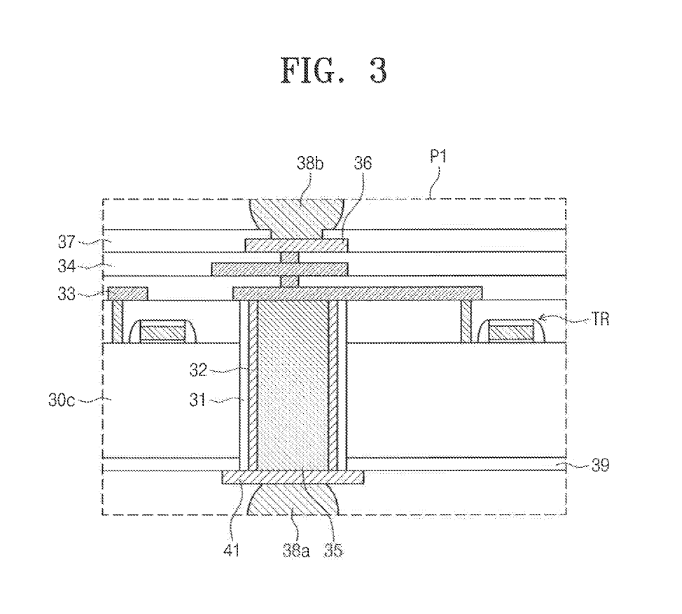

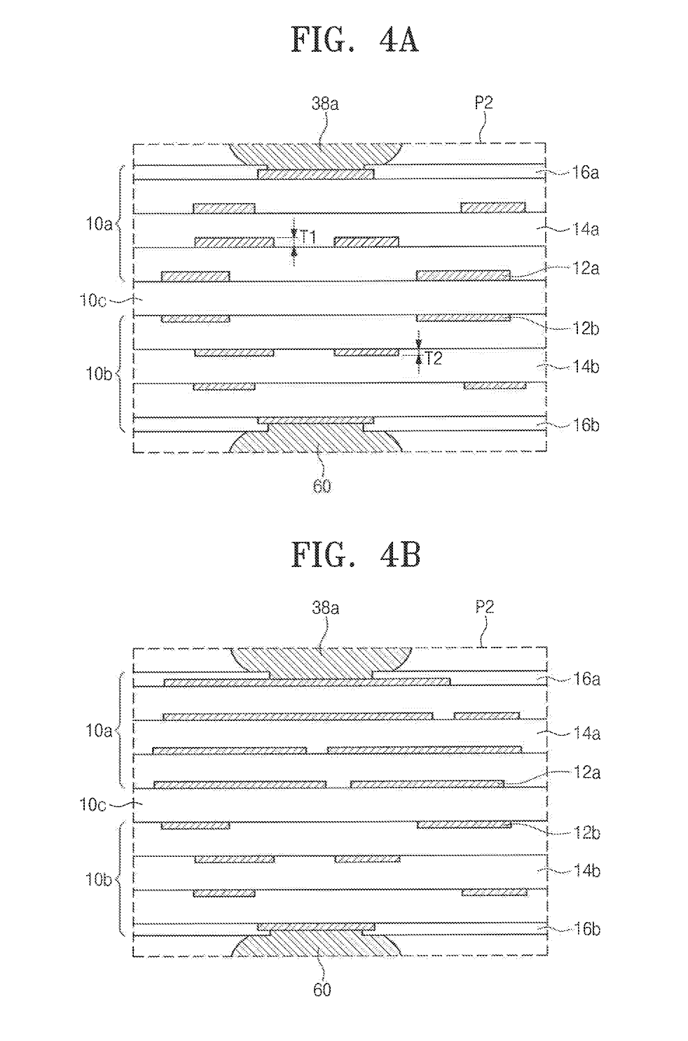

FIG. 1 is a layout diagram illustrating a semiconductor package according to an exemplary embodiment of the inventive concept. FIGS. 2A and 2B are cross-sectional views taken along line I-I′ of FIG. 1. FIG. 2C is a perspective view of the semiconductor package of FIG. 2A, FIG. 3 is an enlarged view of a portion ‘P1’ of FIG. 2A. FIGS. 4A and 4B are enlarged views of a portion ‘P2’ of FIG. 2A.

Referring to FIGS. 1, 2A, 2B, and 2C, a semiconductor package 200 includes a first semiconductor chip 30 and a second semiconductor chip 45 sequentially stacked and mounted on a package substrate 10. For the convenience of a description, the semiconductor package 200 includes two chips 30 and 45, but the umber of the chips included in the semiconductor package is not limited to two. The number of the chips may be at least one. The first semiconductor chip 30 includes at least one through-via 35 penetrating the first semiconductor chip 30. The first semiconductor chip 30 is mounted on the package substrate 10 through first internal solder balls 38a using a flip chip bonding technique. The second semiconductor chip 45 is mounted on the first semiconductor chip 45 through second internal solder balls 38b using a flip chip bonding technique. The internal solder balls 38a and 38b may include at least one of tin, lead, and copper. The semiconductor chips 30 and 45 and the package substrate 10 are covered with a mold layer 24. External solder balls 60 are bonded to a bottom surface of the package substrate 10.

Referring to FIG. 3, the first semiconductor chip 30 includes a substrate part 30c and transistors TR disposed on the substrate part 30c, The transistors TR are covered with interlayer insulating layers 34 stacked on each other. Chip interconnections 33 are disposed between the interlayer insulating layers 34. The through-via 35 penetrates the lowermost interlayer insulating layer of the interlayer insulating layers 34 and the substrate part 30e, and is in contact with at least one of the chip interconnections 33. The through-via 35 may include metal such as copper. A diffusion preventing layer 32 and an insulating layer 31 are conformally disposed between the through-via 35 and the substrate part 30c and between the through-via and the lowermost interlayer insulating layer 34. A bottom surface of the substrate part 30c is covered with a first passivation layer 39. A bottom surface of the through-via 35 is in contact with a first conductive pad 41. A second conductive pad 36 is disposed on the uppermost interlayer insulating layer of the interlayer insulating layers 34. A portion of the second conductive pad 36 and the uppermost interlayer insulating layer 34 are covered with a second passivation layer 37. The first conductive pad 41 and the second conductive pad 36 are in contact with the first internal solder ball 38a and the second internal solder ball 38b, respectively.

A structure of the second semiconductor chip 45 may be the same as or similar to the structure of the first semiconductor chip 30 described above. The second semiconductor chip 45 need not include the through-via 35 as described with reference to FIG. 3.

Referring to FIGS. 4A and 4B, the package substrate 10 is a multi-layered printed circuit hoard. For example, the package substrate 10 includes a core layer 10c, an upper interconnection structure 10a disposed on the core layer 10c, and a lower interconnection structure In disposed under the core layer 10c. The upper interconnection structure 10a includes upper substrate insulating layers 14a and upper interconnections 12a disposed between the upper substrate insulating layers 14a. The lower interconnection structure 10b includes lower substrate insulating layers 14b and lower interconnections 12b disposed between the lower substrate insulating layers 14b. A volume of the upper interconnections 12a in the package substrate 10 may be different from a volume of the lower interconnections 12b in the package substrate 10. For example, in FIGS. 4A and 4B, the volume of the upper interconnections 12a is greater than the volume of the lower interconnections 12b. In FIG. 4A, the thickness T1 of the upper interconnections 12a is greater than the thicknesses T2 of the lower interconnections 12b. Alternatively, in FIG. 4B, the area of the upper interconnections 12a is greater than the area of the lower interconnections 12b, as illustrated in FIG. 4B.

Referring back to FIGS. 1 and 2A to 2C, for example, at least one of the first and second semiconductor chips 30 and 45 may be a memory chip. At least one of the first and second semiconductor chips 30 and 45 may be a logic chip having intellectual property (IP) blocks. The IP blocks may correspond to various devices such as a central processor unit (CPU), a graphic processor unit (GPU), and/or a universal serial bus (USB). Such IP blocks may generate heat to cause operating errors if such heat is not released appropriately. To prevent such operating errors, the operating speeds of the semiconductor chips 30 and 45 may be reduced. The portion which generates heat more than heat generated from other portions may be referred to as a hot spot region H1. The hot spot region H1 is located in a central portion of the first or second semiconductor chip 30 or 45. The heat generated from the hot spot region H1 need to be released to the outside of the semiconductor package 200 to prevent the operating errors and/or the reduction of the operating speed.

The mold layer 24 exposes a central top surface S1 (i.e., a central portion of a top surface) of the second semiconductor chip 45 which overlaps the hot spot region H1. Thus, the heat generated from the hot spot region H1 may be quickly released to the outside of the semiconductor package 200 compared with when the central top surface S1 is covered with the mold layer 24. The mold layer 24 covers the other portions of the semiconductor package 200 except the hot spot region H1. For example, the mold layer 24 covers a top surface of the package substrate 10 and the other portions of the second semiconductor chip 45 except the central top surface Si of the second semiconductor chip 45. The central top surface S1 overlaps the hot spot region H1. The warpage of the semiconductor package 200 due to heat generated therefrom may be suppressed by the mold layer 24.

The structure of the semiconductor package 200 may suppress the semiconductor package 200 from suffering from the warpage phenomenon as compared with a structure of a semiconductor package having a mold layer exposing the entire top surface of the uppermost semiconductor chip 45. Additionally, the semiconductor package 200 may release quickly the heat generated from the semiconductor package 200 as compared with a semiconductor package having a mold layer entirely covering the semiconductor chips 30 and 45. The semiconductor package 200 exposes the central top surface S1 of the uppermost semiconductor chip 45 for heat release. For example, the central top surface S1 overlaps the hot spot region H1 of the semiconductor package 200. The semiconductor package 200 includes the mold 24 entirely covering the semiconductor chips 30 and 45 except for the central top surface S1. Thus, the release of heat is made while the warpage of the semiconductor package 200 is suppressed using the mold layer 24.

Referring to FIGS. 2A and 2C, a top surface S2 of the mold layer 24 is bent or curved. For example, the top surface S2 is concave. In this case, the mold layer 24 have four upper vertexes PM which are positioned higher than the central top surface S1 of the second semiconductor chip 45. The package substrate 10 and the semiconductor chips 30 and 45 may be substantially flat. Alternatively, in FIG. 2B, a top surface S2 of the mold layer 24 is substantially flat. In this case, the package substrate 10 and the semiconductor chips 30 and 45 are convex.

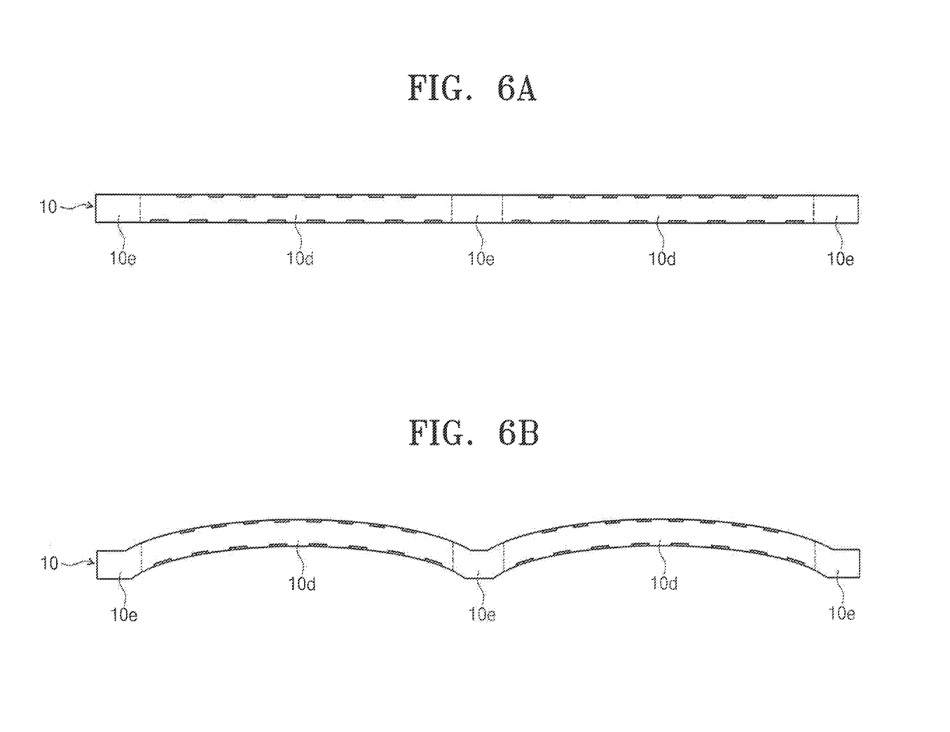

Referring back to FIGS. 2A and 2B and FIGS. 4A and 4B, the interlayer insulating layers 34 of the semiconductor chips 30 and 45 may have a tensile stress. For the convenience of a description, the curvature of the semiconductor package 200 is exaggerated. As the amount of a residual stress increase, the semiconductor package 200 becomes more curved. For example, the semiconductor package 200 of FIG. 2B has a larger residual stress than that of FIG. 2A. If the interconnections 12a and 12b are formed of metal (e.g., copper), the thermal expansion coefficient of the interconnections 12a and 12b is higher than that of the interlayer insulating layers 14a and 14b. Due to the difference in volume expansions between the interconnections 12a and 12b, the semiconductor 200 may be curved in the process of fabricating the semiconductor 200. This will be described later with reference to FIGS. 6A to 10.

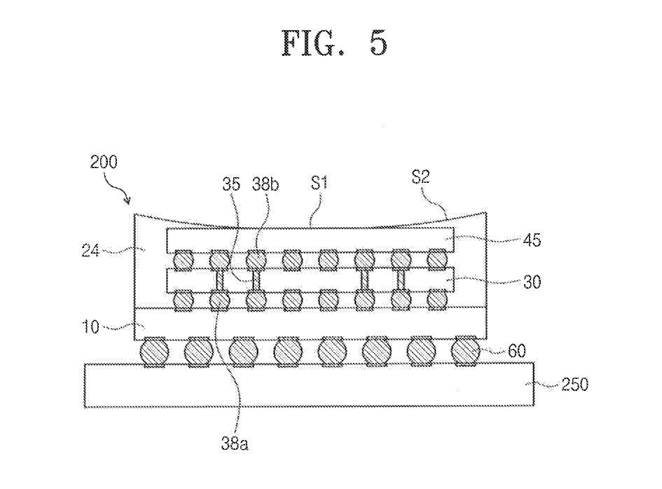

FIG. 5 is a cross-sectional view showing the semiconductor package 200 of FIG. 2A or 2B mounted on a motherboard.

Referring to FIG. 5, the semiconductor package 200 of FIG. 2A is mounted on a motherboard 250. The semiconductor package 10 and the semiconductor chips 30 and 45 are substantially flat, and the top surface S2. of the mold layer 45 is concave. The semiconductor package 200 of FIG. 2B may be mounted on the motherboard 250. As described above, the curvature of the semiconductor package 200 of FIG. 2B is exaggerated for the convenience of a description.

FIGS. 6A, 6B and 7 to 10 are cross-sectional views showing a method of fabricating the semiconductor package of FIG. 2A or 2B.

Referring to FIGS. 6A and 6B, a package substrate 10 is formed. As described with reference to FIGS. 4A and 4B, volumes of upper and lower interconnections 12a and 12b of the package substrate 10 may be different from each other when the package substrate 10 is formed. The package substrate 10 may be a multi-layered printed circuit board. The package substrate 10 includes chip-mounting regions 10d and a non-mounting region 10e disposed between the chip-mounting regions 10d. Semiconductor chips 30 and 45 may be mounted on each of the chip mounting regions 10d. Each of the chip-mounting regions 10d may include the upper and lower interconnections 12a and 12b constituting various circuits, as described with reference to FIGS. 4A and 4B. The upper and lower interconnections 12a and 12b need not be disposed in the non-mounting region 10e. The package substrate 10 of FIG. 6A may be subject to a high temperature. For example, the high temperature may range between about 200° C. and about 350° C. As illustrated in FIG. 6B, when the package substrate 10 is subject to the high temperature, the chip-mounting regions 10d becomes convex due to a distribution difference between the upper and the lower interconnections 12a and 12b and/or a difference in volume expansion between the upper and the lower interconnections 12a and 12b. Alternatively, the package substrate 10 may be entirely flat before the semiconductor chips 30 and 45 are mounted, as illustrated in FIG. 6A.

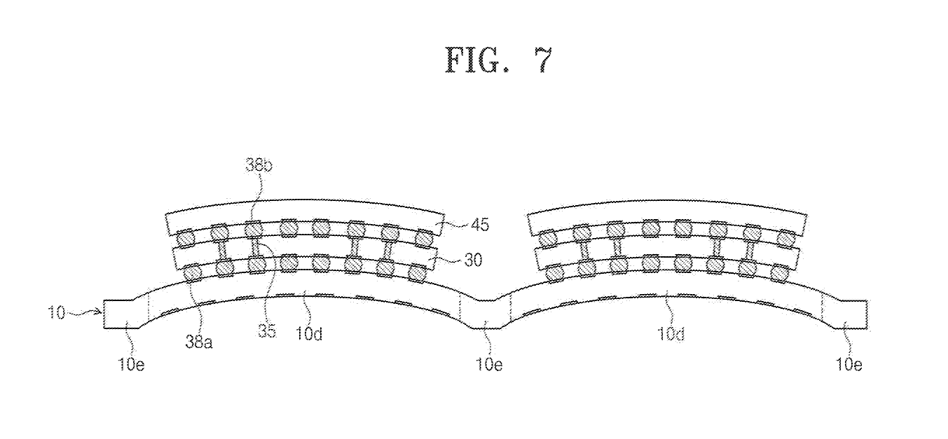

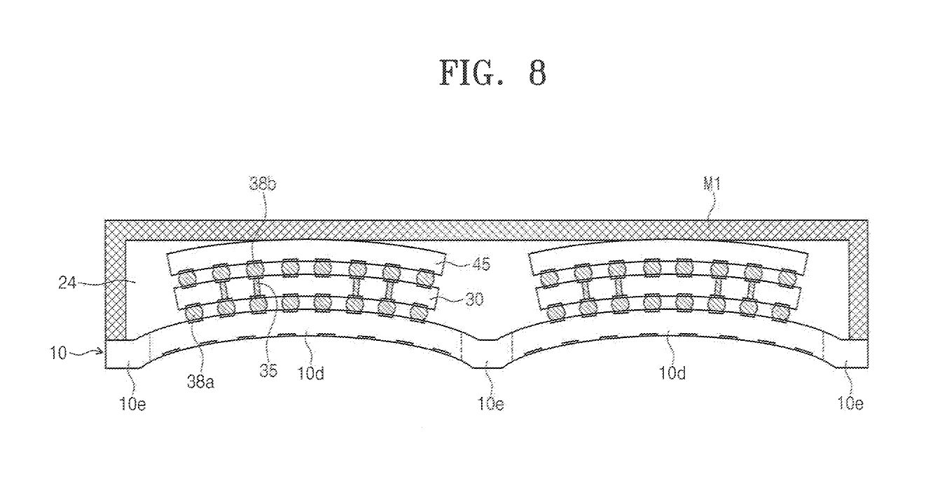

Referring to FIG. 7, the semiconductor chips 30 and 45 are formed. Process apparatuses and/or process recipes for forming interlayer insulating layers 34 in the semiconductor chips 30 and 45 may be controlled such that a residual stress of the interlayer insulating layers 34 is a tensile stress when the semiconductor chips 30 and 45 are formed. For example, the stacking of the semiconductor chips 30 and 45 may be performed in a high temperature that ranges, for example, between about 200° C. and about 350° C. A first semiconductor chip 30 and a second semiconductor chip 45 may be sequentially stacked and mounted on each of the chip-mounting regions 10d by a flip chip bonding technique using internal solder balls 38a and 38b. At this time, a heating process may be performed at a temperature equal to or greater than a melting point of the internal solder balls 38a and 38b. The chip-mounting regions 10d of the package substrate 10 may become convex by the process temperature of the heating process. Since the chip-mounting regions 10d become convex upward even though the semiconductor chips 30 and 45 are substantially flat before the mounting process, the semiconductor chips 30 and 45 may become convex upward after the mounting process. In this ease, the thickness of the semiconductor chips 30 and 45 may range between about 50 μm and about 100 μm. A convex degree (or a warpage degree) of the package substrate 10 and the semiconductor chips 30 and 45 may be slightly relieved by a cooling process performed after the mounting process. However, some of the convex degree (or the warpage degree) may remain due to a difference between material properties of the semiconductor chip 10 and the semiconductor chips 30 and 45. For example, such cooling process may occur when the resulting structure of FIG. 7 is transferred to the next process stage of FIG. 8 which will be described below. If the next process stage of FIG. 8 is performed in a continuous manner, the cooling process may be omitted.

Referring to FIG. 8, the package substrate 10 is covered with a mold frame M1. A mold resin solution is then supplied into an inner space of the mold frame M1. At this time, the mold frame M1 is in contact with a central portion of a top surface of the second semiconductor chip 45 to prevent the mold resin solution from covering the central top surface of the second semiconductor chip 45. For example, the mold resin solution fills an entire portion of the inner space of the mold frame M1 except for the central top surface of the second semiconductor chip 45. Alternatively, the mold resin solution may partially fill the inner space such that the central top surface of the second semiconductor chip 45 is exposed. Subsequently, the mold resin solution is hardened by heat to form a mold layer 24.

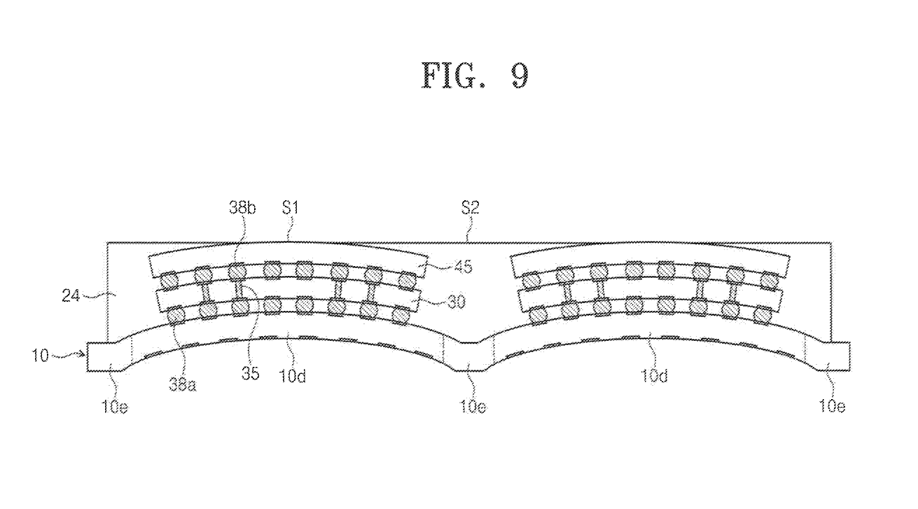

Referring to FIG. 9, the mold frame M1 is removed and the mold layer 24 is exposed. The central top surface S1 of the second semiconductor chip 45 is not covered with the mold layer 24.

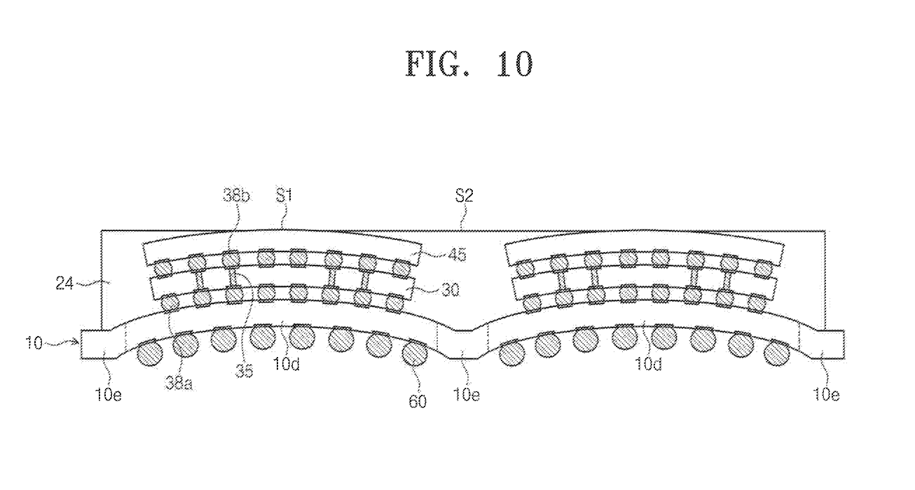

Referring to FIG. 10, external solder balls 60 are bonded to a bottom surface of the package substrate 10.

A singulation process is performed on the resulting structure of FIG. 10 to form individual semiconductor packages 200 as shown in FIGS. 2A and 2B. The non-mounting region 10e and the mold layer 24 on the non-mounting region 10e are removed or cut away in the singulation process. After the semiconductor packages 200 are cooled to the room temperature, the package substrate 10 of the individual semiconductor package 200 may become substantially flat. In this case, the residual stress need not be completely released in the cooling process. According to the amount of the residual stress, the semiconductor package 200 may have the curved shapes of FIGS. 2A and 2B. Since the package substrate 10 becomes substantially flat, the semiconductor chips 30 and 45 mounted on the package substrate 10 may become substantially flat. As a result, the top surface S2 of the mold layer 24 may become concave, as shown in FIG. 2A. Alternatively, as shown in FIG. 2B, the package substrate 10 and the semiconductor chips 30 and 45 are convex, and the top surface S2 of the mold layer 24 is substantially flat.

In an exemplary method of fabricating a semiconductor package according to the present inventive concept, the package substrate 10 and/or the semiconductor chips 30 and 45 may first be convex due to heat applied in the process of fabricating the semiconductor package. After cooling of the package substrate 10, the package substrate 10 may become substantially flat. Such flattening of the package substrate 10 may cause the top surface of the second semiconductor package 45 to be concave. The central top surface SI of the second semiconductor chip 45 need not be covered with the mold layer 24, and may overlap at least a portion of the hot spot region H1 disposed at a. central portion of the semiconductor package 200. For example, as shown in FIGS. 4A and 4B, the volume of the upper interconnections 12a may be greater than the volume of the lower interconnections 12b in the package substrate 10, and/or the interlayer insulating layers 34 of the semiconductor chips 30 and 45 may have a residual stress of a tensile stress. Thus, the central top surface S1 of the second semiconductor chip 45 may be exposed without performing an additional process of forming an opening exposing the central top surface S1. As a result, the fabricating processes of the semiconductor package 200 may be simplified. In addition, it is possible to prevent damage of the second semiconductor chip 45 caused by the additional process of forming the opening.

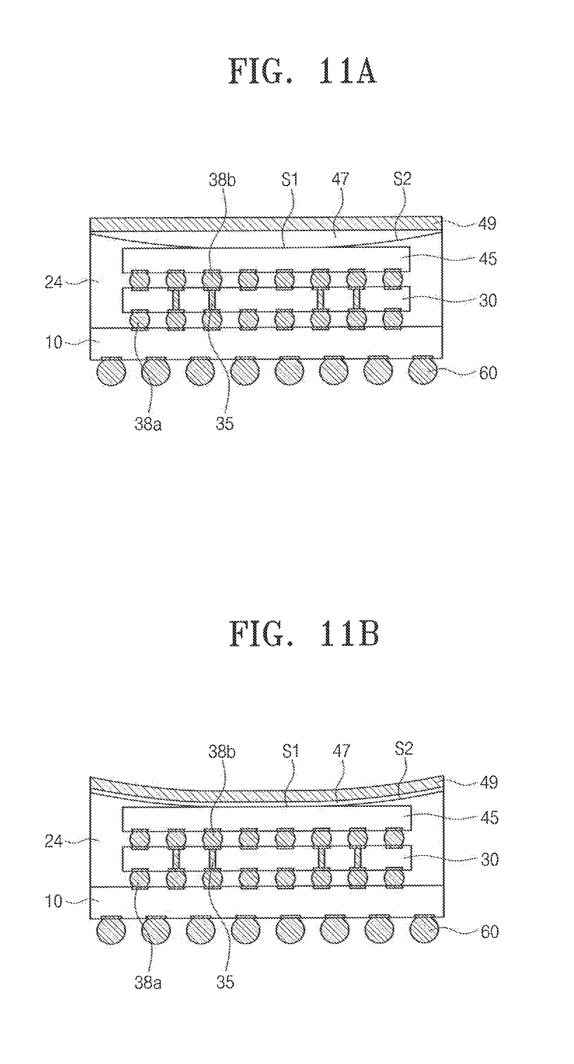

FIGS. 11A and 11B are cross-sectional views showing exemplary, modified embodiments of the semiconductor package of FIG. 2A.

Referring to FIG. 11A, a semiconductor package 201a includes a thermal boundary material layer 47 which is in contact with the exposed central top surface S1 of the second semiconductor chip 45 and the top surface S2 of the mold layer 24 in FIG. 2A. A heat dissipating member 49 is disposed on the thermal boundary material layer 47. The thermal boundary material layer 47 may include an adhesive layer, thermal grease, or thermal epoxy. At least one of the adhesive layer, the thermal grease, and the thermal epoxy may include metal solid particles. The heat dissipating member 49 may be a metal plate or a metal tape having flexibility. The thermal boundary material layer 47 is varied in thickness according to a position of a corresponding portion of the thermal boundary material layer 47 on the second semiconductor chip 45. For example, the thermal boundary material layer 47 may be the thickest on a central portion of the second semiconductor chip 45 and may be the thinnest on an upper vertex of the second semiconductor chip 45. Other elements of the semiconductor package 201a may be the same as or similar to corresponding elements of the semiconductor package 200 of FIG. 2A.

Referring to FIG. 11B, a semiconductor package 201b includes a thermal boundary material layer 47 and a heat dissipation member 49 which are sequentially stacked on the exposed central top surface S1 of the second semiconductor chip 45 and the top surface S2 of the mold layer 24 illustrated in FIG. 2A. The thermal boundary material layer 47 is uniform in thickness. Other elements of the semiconductor package 201b may be the same as or similar to corresponding elements of the semiconductor package 201a described with reference to FIG. 11A.

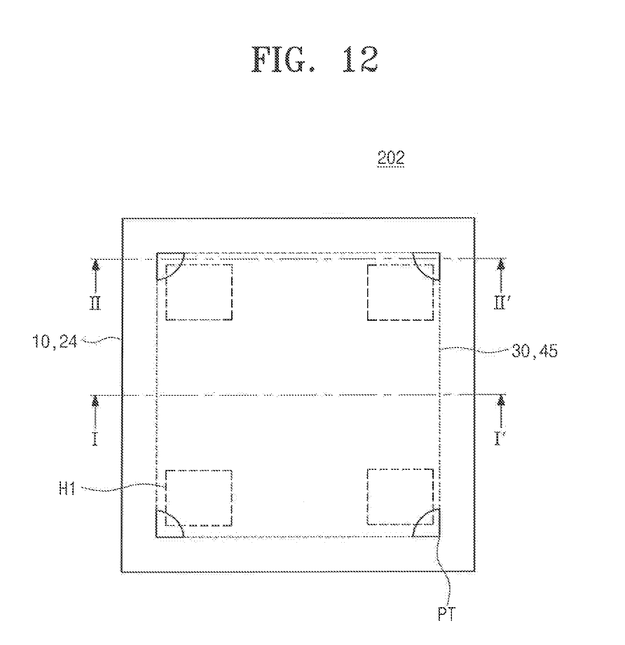

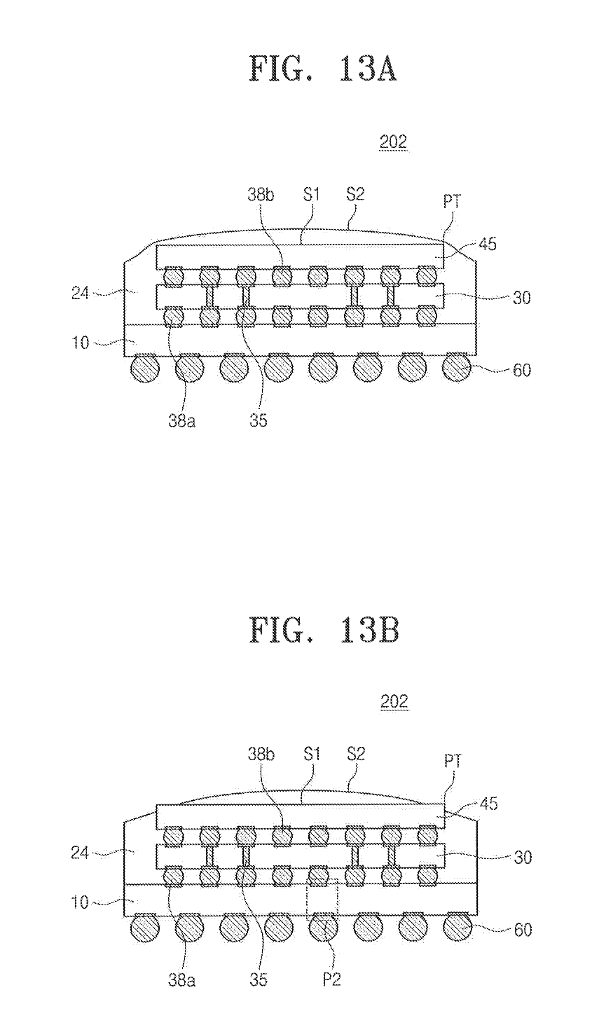

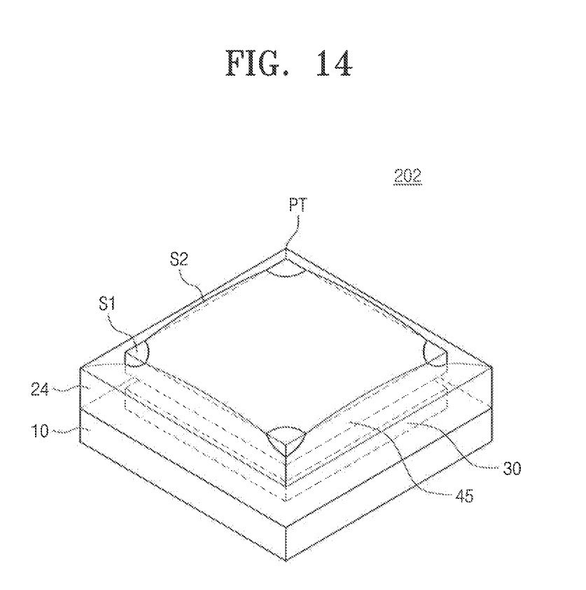

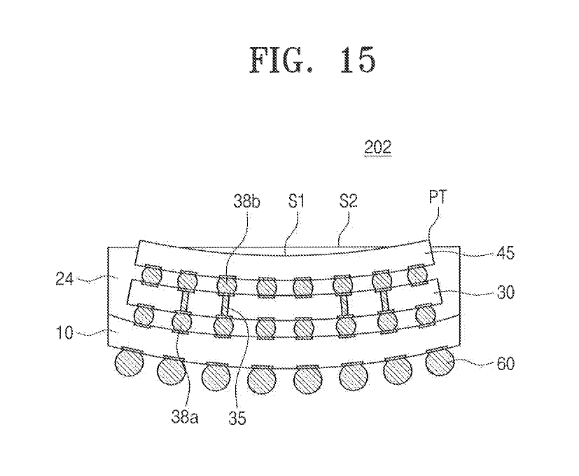

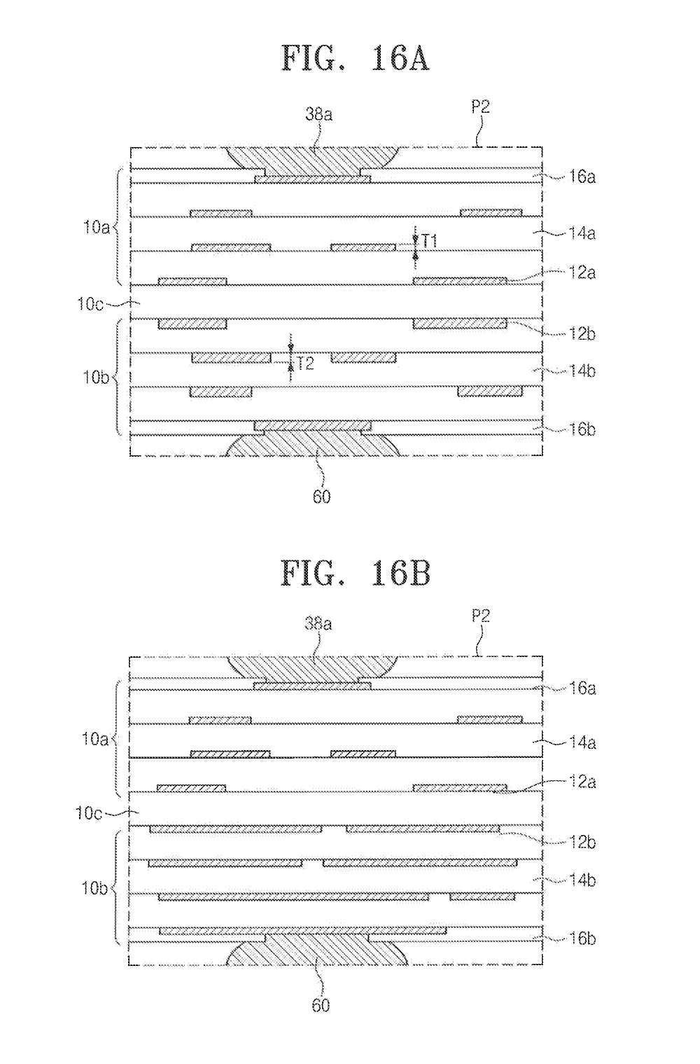

FIG. 12 is a layout diagram showing a semiconductor package according to an exemplary embodiment of the inventive concept. FIG. 13A is a cross-sectional view taken along line I-I′ of FIG. 12. FIGS. 13B and 15 are cross-sectional views taken along line II-II′ of FIG. 12. FIG. 14 is a perspective view showing the semiconductor packages of FIGS. 13A and 13B. FIGS. 16A and 16B are enlarged views of a portion ‘P2’ of FIG. 13B.

Referring to FIGS. 3, 12, 13A, 13B, 14, and 15, a first semiconductor chip 30 and a second semiconductor chip 45 are sequentially stacked and mounted on a package substrate 10 in a semiconductor package 202. The first semiconductor chip 30 may include transistors TR, interlayer insulating layers 34, chip interconnections 33, and at least one through-via 35, as described with reference to FIG. FIG. 3. The second semiconductor chip 45 may include transistors TR, interlayer insulating layers 34, and chip interconnections 33 except the through-via 35. One of the first and second semiconductor chips 30 and 45 may be a logic chip and may have hot spot regions H1. The hot spot regions H1 may be disposed in regions adjacent to vertex portions of the first or second semiconductor chip 30 or 45. The first and second semiconductor chips 30 and 45 and the package substrate 10 are covered with a mold layer 24. The mold layer 24 covers a central top surface SI of the second semiconductor chip 45 and does not cover upper vertexes PT of the second semiconductor chip 45. Thus, the hot spot regions H1 or portions of the second semiconductor chip 45 adjacent to the hot spot regions H1 are not covered with the mold layer 24, so heat generated from the hot spot regions H1 may be released to the outside of the semiconductor package 202 through the exposed upper vertexes PT.

In FIGS. 13A and 13B, a top surface S2 of the mold layer 24 is convex upward and rounded, and the package substrate 10 and the first and second semiconductor chips 30 and 45 are substantially flat. Alternatively, in FIG. 15, a top surface S2 of the mold layer 24 is substantially flat, but top surfaces of the package substrate 10 and the first and second semiconductor chips 30 and 45 are bent or concave downward. In this case, a residual stress of the interlayer insulating layers 34 of the first and second semiconductor chips 30 and 45 may be a compressive stress.

The package substrate 10 of FIGS. 13A, 13B, 14 and 15 may have a multi-layered printed circuit board different from FIGS. 4A and 4B. Referring to FIGS. 16A and 16B, the package substrate 10 includes a core layer 10c, an upper interconnection structure 10a disposed on the core layer 10c, and a lower interconnection structure 10b disposed under the core layer 10c. The upper interconnection structure 10a includes upper substrate insulating layers 14a and upper interconnections 12a disposed between the upper substrate insulating layers 14a, The lower interconnection structure 10b includes lower substrate insulating layers 14b and lower interconnections 12b disposed between the lower substrate insulating layers 14b. A volume of the upper interconnections 12a is less than a volume of the lower interconnections 12b. For example, in FIG. 16A, a thickness T1 of the upper interconnections 12a is smaller than a thickness T2 of the lower interconnections 12b. Alternatively, as shown in FIG. 16B, an area of the upper interconnections 12a is smaller than an area of the lower interconnections 12b. The interconnections 12a and 12b are formed of a metal (e.g., copper) and have a higher thermal expansion coefficient than that of the insulating layer 14a and 14b. Volume expansion difference between the interconnections 12 and 12b due to heat may cause the package substrate 10 to become concave downward in the process of fabricating.

The semiconductor package 202 includes exposed portions that overlap the hot spot regions H1, and thus heat applied to fabricate the semiconductor package 202 is released through the exposed portions. Accordingly, warpage of the semiconductor package 202 may be reduced.

Other elements of the semiconductor package 202 may be the same as or similar to corresponding elements described with reference to FIGS. 1, 2A to 2C, 3, 4A, and 4B.

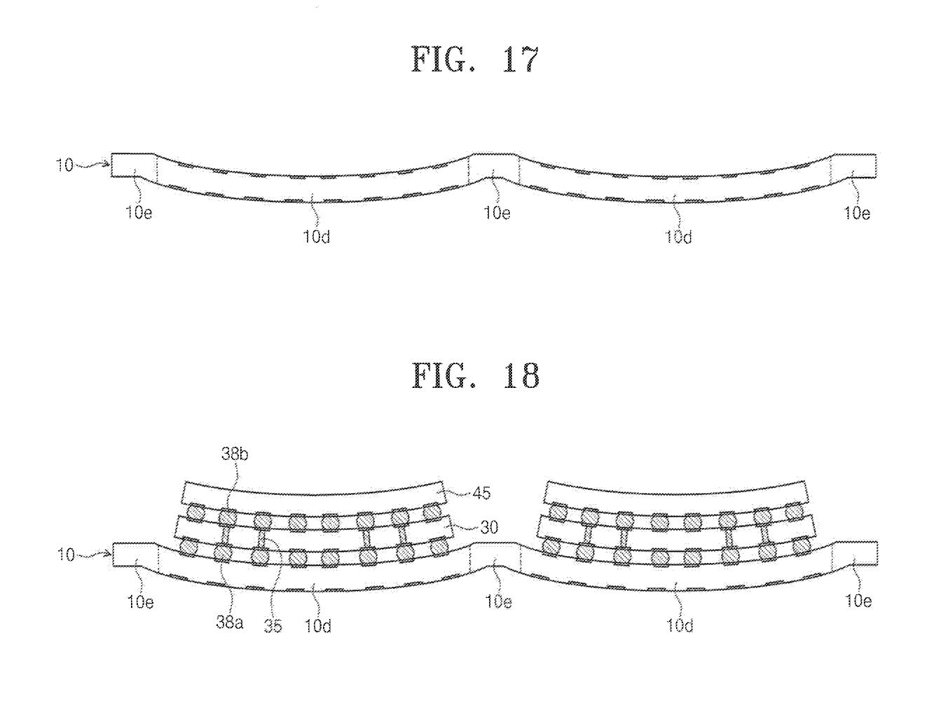

FIGS. 17 to 19 are cross-sectional views showing an exemplary method of fabricating the semiconductor package of FIGS. 13B and 15 according to the present inventive concept.

Referring to FIGS. 6A and 17, a package substrate 10 is formed. As described with reference to FIGS. 16A and 16B, the volumes of the upper and lower interconnections 12a and 12b may be different from each other when the package substrate 10 is formed. The package substrate 10 may be a multi-layered printed circuit hoard. The package substrate 10 includes chip-mounting regions 10d and a non mounting region 10e disposed between the chip-mounting regions 10d. Semiconductor chips 30 and 45 are mounted on each of the chip-mounting regions 10d. Each of the chip-mounting regions 10d includes upper and lower interconnections 12a and 12b constituting various circuits, as described with reference to FIGS. 16A and 16B, The upper and lower interconnections 12a and 12b need not be disposed in the non mounting region 10e. In FIG. 17, if the package substrate 10 is subject to a high temperature, the chip-mounting regions 10d are concave downward by a distribution difference between the upper and the lower interconnections 12a and 12b and a difference in volume expansion between the upper and the lower interconnections 12a and 12b. Alternatively, the package substrate 10 may be entirely flat before the semiconductor chips 30 and 45 are mounted.

Referring to FIG. 18, the semiconductor chips 30 and 45 are formed. Process apparatuses and/or process recipes for forming interlayer insulating layers 34 in the semiconductor chips 30 and 45 may be controlled such that a residual stress of the interlayer insulating layers 34 may be a compressive stress when the semiconductor chips 30 and 45 are formed. A first semiconductor chip 30 and a second semiconductor chip 45 may be sequentially stacked and mounted on each of the chip-mounting regions 10d by a flip chip bonding technique using internal solder balls 38a and 38b. At this time, a heating process may be performed at a temperature equal to or greater than a melting point of the internal solder balls 38a and 38b. The chip-mounting regions 10d of the package substrate 10 may become concave downward by the process temperature of the heating process. Since the chip-mounting regions 10d become concave downward even though the semiconductor chips 30 and 45 are substantially flat before the mounting process, the semiconductor chips 30 and 45 may become concave downward after the mounting process. The concave state of the package substrate 10 and the semiconductor chips 30 and 45 may be slightly relieved by a cooling process performed after the mounting process. However, some degree of the concave state of the package substrate 10 and the semiconductor chips 30 and 45 may remain due to a difference in properties of materials of the semiconductor chip 10 and the semiconductor chips 30 and 45. Alternatively, if the fabrication process is performed in a continuous manner, such cooling process may be omitted.

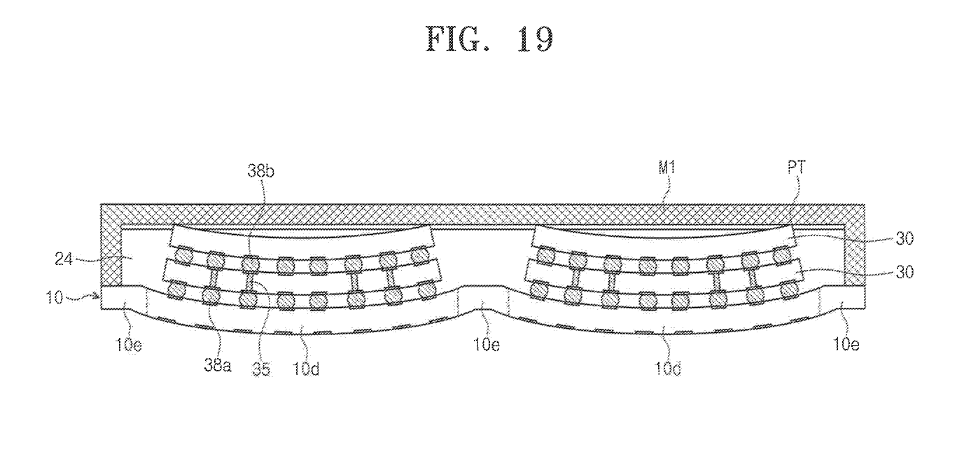

Referring to FIG. 19, the package substrate 10 is covered with a mold frame M1, and a mold resin solution is then supplied into the mold frame M1 to entirely fill an inner space of the mold frame M1. The mold frame M1 is in contact with vertexes PT of the second semiconductor chip 45. Thus, the mold resin solution does not cover the vertexes PT of the second semiconductor chip 45 that is in contact with the mold frame M1. Alternatively, a supply amount of the mold resin solution may be controlled to partially fill the inner space of the mold frame M1 with the mold resin solution such that the vertexes PT and adjacent portions thereto of the second semiconductor chip 45 are not covered with the mold resin solution. The mold resin solution is hardened by applying heat to form a mold layer 24.

The mold frame M1 is removed to expose a surface of the mold layer 24 as shown in FIG. 15. At this time, the vertexes PT of the second semiconductor chip 45 are exposed. External solder balls 60 are bonded to a bottom surface of the package substrate 10. A singulation process is performed to form individual semiconductor packages 202. The non-mounting region 10e and the mold layer 24 on the non mounting region 10e are removed or cut away in the singulation process. The heat applied in the processes is released, so the package substrate 10 of the individual semiconductor package 200 may become substantially flat. Since the package substrate 10 becomes substantially flat, the semiconductor chips 30 and 45 mounted on the package substrate 10 may become substantially flat. As a result, the top surface S2 of the mold layer 24 become convex, as shown in FIGS. 13 and 13B. Alternatively, as illustrated in FIG. 15, the package substrate 10 and the semiconductor chips 30 and 45 may stay concave, and the top surface S2 of the mold layer 24 is substantially flat

In an exemplary method of fabricating a semiconductor package according to the inventive concept, the package substrate 10 and/or the semiconductor chips 30 and 45 may be formed to be concave in advance for exposing the vertexes PT of the second semiconductor chip 45 overlapping at least portions of the hot spot regions H1. For example, the volume of the upper interconnections 12a may be less than the volume of the lower interconnections 12b in the package substrate 10, and/or the interlayer insulating layers 34 of the semiconductor chips 30 and 45 may be formed to have a remaining stress of a compressive stress. Thus, the vertexes PT of the second semiconductor chip 45 may be exposed without an additional process of forming openings exposing the vertexes PT. As a result, the fabricating processes of the semiconductor package 202 may be simplified. In addition, it is possible to prevent damage of the second semiconductor chip 45 caused by the additional process of forming the openings.

In the aforementioned methods of fabricating the semiconductor package, the portion exposed by the mold layer may be determined depending on the position of the hot spot region disposed within the semiconductor chip. The remaining stress of the interlayer insulating layer of the semiconductor chip may be controlled and/or the volumes of the interconnections within the package substrate may be controlled differently from each other, and thus, the warpage degree of the semiconductor chip and/or the package substrate may be controlled to expose the portion adjacent to the hot spot region.

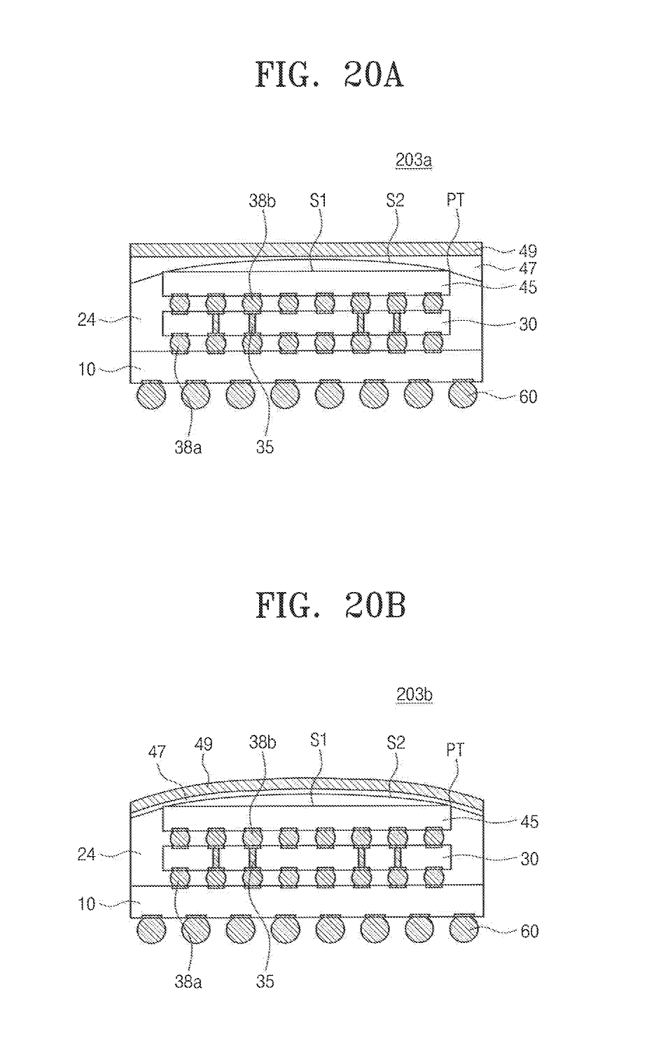

FIGS. 20A and 20B are cross-sectional views showing exemplary, modified embodiments of the semiconductor package of FIG. 13B according to the inventive concept.

Referring to FIG. 20A, a semiconductor package 203a includes a thermal boundary material layer 47 which is in contact with the exposed vertexes PT of the second semiconductor chip 45 and the top surface S2 of the mold layer 24 of FIG. 13B. The semiconductor package 203a further includes a heat dissipation member 49 disposed on the thermal boundary material layer 47. In FIG. 20A, the thickness of the thermal boundary material layer 47 is varied according to a position of a corresponding portion of the thermal boundary material layer 47 on the second semiconductor chip 45. For example, the thermal boundary material layer 47 may be the thinnest on a central portion of the second semiconductor chip 45 and may be the thickest on the upper vertex of the second semiconductor chip 45. Other elements of the semiconductor package 201a may be the same as or similar to corresponding elements of the semiconductor package 202 of FIG. 13B.

Referring to FIG. 20B, a semiconductor package 203b includes a thermal boundary material layer 47 which is in contact with the exposed vertexes PT of the second semiconductor chip 45 and the top surface S2 of the mold layer 24 of FIG. 13B. The semiconductor package 203b further includes a heat dissipation member 49 disposed on the thermal boundary material layer 47. In this case, a thickness of the thermal boundary material layer 47 is substantially uniform.

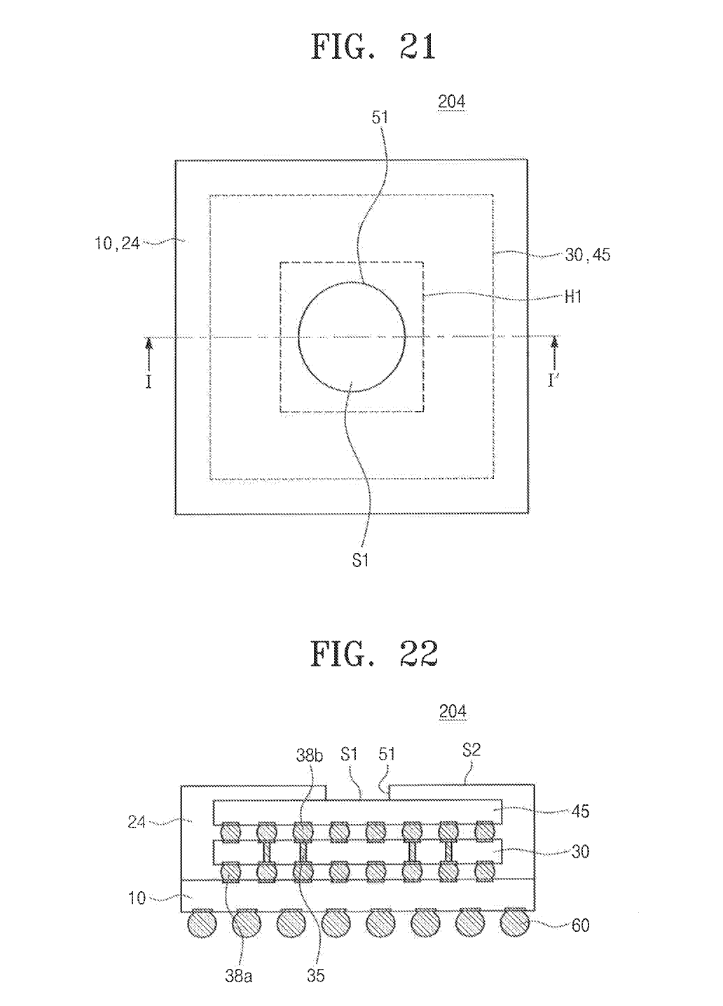

FIG. 21 is a layout diagram showing a semiconductor package according to an exemplary embodiment of the inventive concept. FIG. 22 is a cross-sectional view taken along line I-I′ of FIG. 21.

Referring to FIGS. 21 and 22, a semiconductor package 204 includes a mold layer 24 having an opening 51. The opening 51 overlaps a hot spot region H1 of at least one of semiconductor chips 30 and 45. The opening 51 exposes a top surface S1 of the second semiconductor chip 45. In FIG. 22, top surfaces of the mold layer 24, the package substrate 10, and the semiconductor chips 30 and 45 are substantially flat. However, the inventive concept is not limited thereto. For example, the top surfaces of the mold layer 24, the package substrate 10, and the semiconductor chips 30 and 45 may be convex upward or concave downward. Other elements of the semiconductor package 204 may be the same as or similar to corresponding elements of the semiconductor packages described above.

The mold layer 24 may include at least one opening 51. Positions of the at least one opening 51 may be various. The semiconductor package 204 may further include the thermal boundary material layer 47 and a heat dissipation member 49 of FIGS. 20A and 20B.

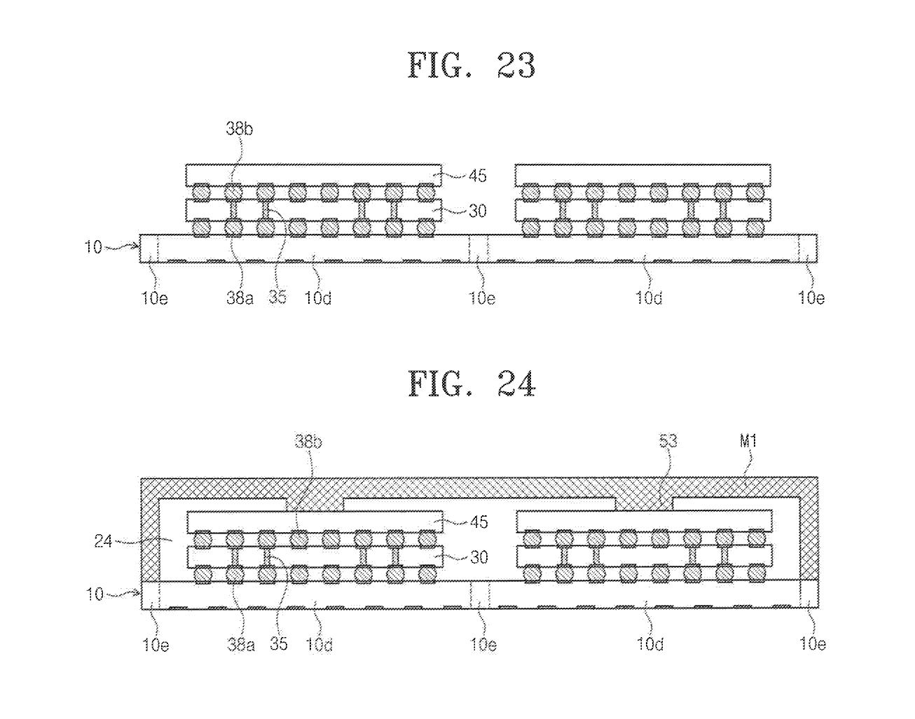

FIGS. 23 and 24 are cross-sectional views showing a method of fabricating a semiconductor package of FIG. 22.

Referring to FIG. 23, semiconductor chips 30 and 45 are sequentially stacked and mounted on a chip-mounting region 10d of a package substrate 10.

Referring to FIG. 24, the package substrate 10 is covered with a mold frame M2. At this time, the mold frame M2 includes a protrusion 53 protruding downward from an inner top surface of the mold frame M2. The protrusion 53 is in contact with a top surface of the second semiconductor chip 45. A mold resin solution is provided into an inner space of the mold frame M2. to fill the inner space. The mold resin solution is hardened by heat applied to form a mold layer 24.

The same subsequent process as or similar subsequent processes to those described above may be performed.

The opening 51 of the mold frame M2 may have various shapes, exposing the top surface of the semiconductor chip 45 that overlaps hot spots of the chips 30 and 45 and simplifying the fabricating processes of the semiconductor package 204. Such simplified process may prevent damage of the semiconductor chip 45.

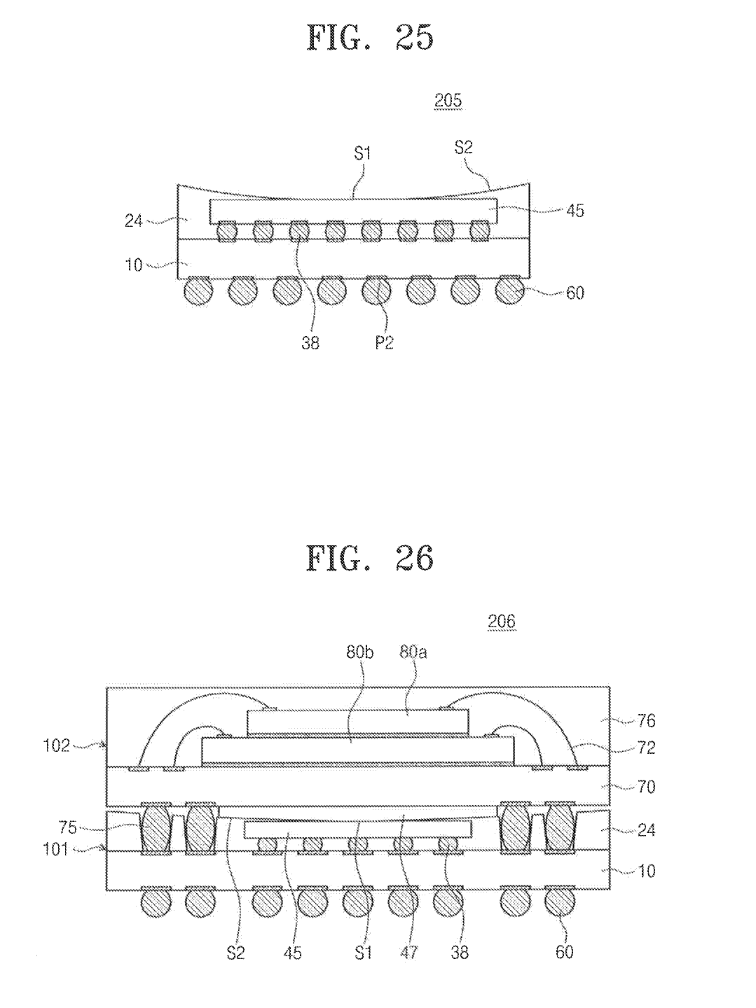

FIGS. 25 and 26 are cross-sectional views showing semiconductor packages according to an exemplary embodiment of the inventive concept.

Referring to FIG. 25, a semiconductor package 205 includes one semiconductor chip 45. A mold layer 24 exposes a central top surface S1 of the semiconductor chip 45 but covers an edge of the semiconductor chip 45. A top surface S2 of the mold layer 24 is curved. Other elements of the semiconductor package 205 may be the same as or similar to corresponding elements of the semiconductor package 200 of FIG. 2A.

Referring to FIG. 26, a package-on-package (PoP) device includes a semiconductor package 206 according to an exemplary embodiment of the present embodiment. The package-on-package (PoP) device 206 includes a first sub semiconductor package 101 and a second sub-semiconductor package 102 mounted on the first sub-semiconductor package 101. The first sub-semiconductor package 101 may have a substantially same structure as the semiconductor package 205 of FIG. 25. The second sub-semiconductor package 102 includes an upper package substrate 70 and upper semiconductor chips 80a and 80b mounted on the upper package substrate 70. The upper semiconductor chips 80a and 80b are electrically connected to the upper package substrate 70 using wires 72 formed by a wire bonding technique. An upper mold layer 76 covers the upper semiconductor chips 80a and 80b and the upper package substrate 70. The package substrate 10 of the first sub-semiconductor package 101 is electrically connected to the upper package substrate 70 of the second sub semiconductor package 102 through interconnecting solder balls 75 penetrating the mold layer 24 of the first sub-semiconductor package 101. A thermal boundary material layer 47 is disposed between the first sub-semiconductor package 101 and the second sub-semiconductor package 102. Other elements of the semiconductor package 206 may be the same as or similar to corresponding elements of the semiconductor package 205 of FIG. 25.

The various exemplary structures and fabricating methods of the semiconductor packages 200, 201a, 201b, 202, 203a, 203b, 204, 205, and 206 are described using exemplary embodiments of the inventive concept. The semiconductor packages 200, 201a, 201b, 202, 203a, 203b, 204, 205, and 206 may be combined with each other in various ways.

The semiconductor package techniques described above may be applied to various kinds of semiconductor devices and package modules including the semiconductor devices.

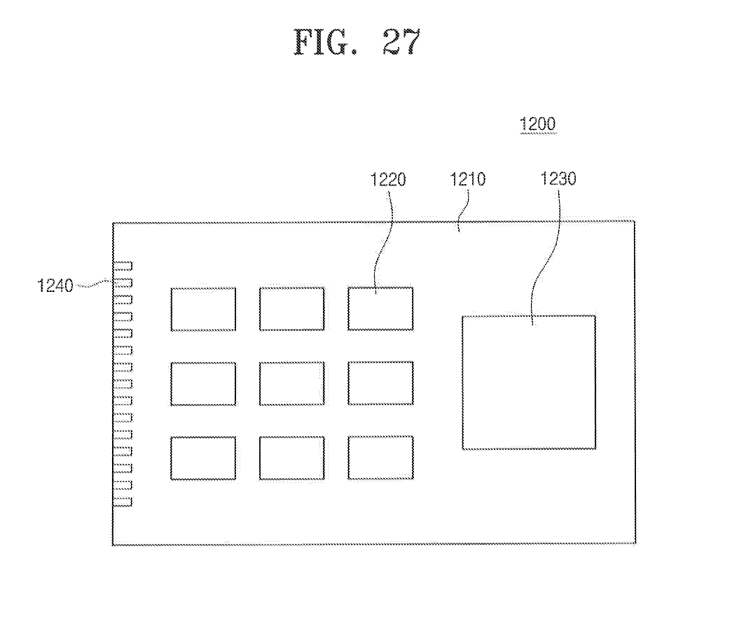

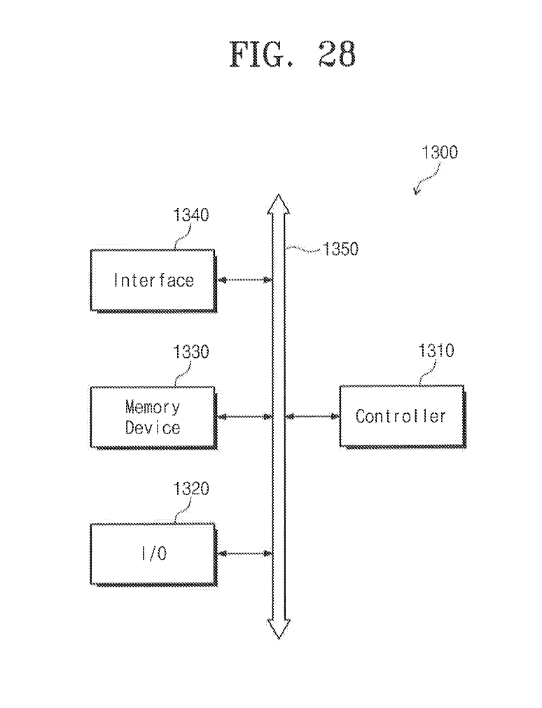

FIG. 27 is a schematic diagram showing an exemplary package module according to the present inventive concept. Referring to FIG. 27, a package module 1200 includes first semiconductor integrated circuit chips 1220 and a second semiconductor integrated circuit chip 1230 packaged using a quad flat package (QFP) technique. The semiconductor integrated circuit chips 1220 and 1230 may be formed according to an exemplary embodiment of the inventive concept. The chips 1220 and 1230 are mounted on a module board 1210 to form the package module 1200. The package module 1200 may be connected to an external electronic device through external connection terminals 1240 provided on a side of the module board 1210.

The aforementioned semiconductor package technique may be applied to an electronic system. FIG. 28 is a schematic block diagram showing an exemplary electronic system according to the present inventive concept. The electronic system 1300 includes a semiconductor package according to an exemplary embodiment of the inventive concept. Referring to FIG. 28, the electronic system 1300 includes a controller 1310, an input/output (I/O) unit 1320, and a memory device 1330. The controller 1310, the I/O unit 1320, and the memory device 1330 may communicate with each other through a data bus 1350. The data bus 1350 may correspond to a path through which electrical signals are transmitted. For example, the controller 1310 may include at least one of a microprocessor, a digital signal processor, a microcontroller, and other logic devices having a similar function to any one thereof. Each of the controller 1310 and the memory device 1330 may include at least one semiconductor package according to an exemplary embodiment of the inventive concept. The I/O unit 1320 may include at least one of a keypad, a keyboard, and a display unit. The memory device 1330 is a device configured to store data. The memory device 1330 may store data and/or commands executed by the controller 1310. The memory device 1330 may include a volatile memory device and/or a non-volatile memory device. For example, the memory device 1330 may include a flash memory device. For example, the flash memory device applied with the technique according to the inventive concept may be installed in an information processing system such as a mobile device or a desk top computer. The flash memory device may be implemented as solid state disks (SSD). In this case, the electronic system 1300 may store massive data in the memory device 1330. The electronic system 1300 may further include an interface unit 1340 that transmits electrical data to a communication network or receives electrical data from a communication network. The interface unit 1340 may support wireless and/or cable communication. For example, the interface unit 1340 may include an antenna for wireless communication or a transceiver for cable communication. Although not shown in the drawings, the electronic system 1300 may further include an application chipset and/or a camera image processor (CIS).

The electronic system 1300 may be implemented as a mobile system, a personal computer, an industrial computer, or a multi-functional logic system. For example, the mobile system may be one of a personal digital assistant (PDA), portable computer, a web tablet, a wireless phone, a mobile phone, a laptop computer, a digital music player, a memory card, or an information transmitting/receiving system. If the electronic system 1300 is an apparatus capable of performing wireless communication, the electronic device 1300 may be used in a communication interface protocol such as a communication system such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, or MMDS.

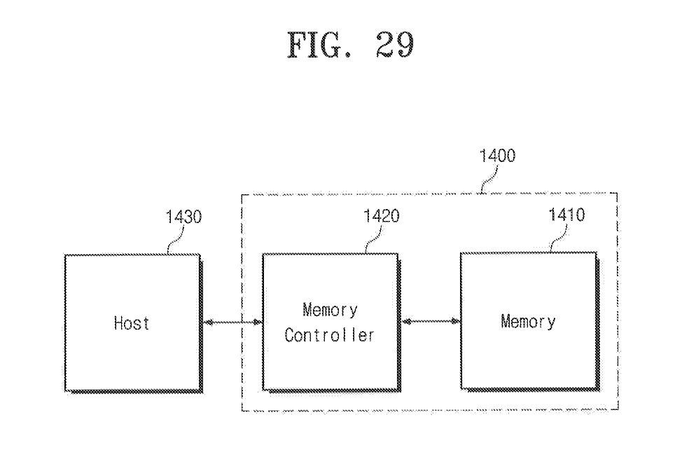

A semiconductor package according to an exemplary embodiment of the inventive concept may be applied to a memory card. FIG. 29 is a schematic block diagram showing an exemplary memory card according to the inventive concept. The memory card 1400 includes a semiconductor package according to an exemplary embodiment of the inventive concept. The memory card 1400 includes a non-volatile memory device 1410 and a memory controller 1420. The non-volatile memory device 1410 and the memory controller 1420 may store data or may read stored data. The non volatile memory device 1410 may include at least one of nonvolatile memory devices applied with the semiconductor package techniques according to the inventive concept. The memory controller 142.0 may read data from/store data into the non-volatile memory device 1410 in response to read/write request of a host 1430.

According to an exemplary embodiment of the inventive concept, a mold layer does not cover a region of a semiconductor chip that is adjacent to the hot spot region, covering the other regions of the semiconductor chip. Thus, heat applied to the semiconductor chip in the fabrication process may be released through the exposed region of the semiconductor chip, and thus the warpage of the semiconductor package may be reduced.

According to an exemplary embodiment of the inventive concept, the amount of warpage in the package substrate and/or the semiconductor chip may be controlled before the formation of a mold layer such that a portion of the semiconductor chip is exposed without using an additional process of forming an opening. Thus, the fabricating processes may be simplified.

According to an exemplary embodiment of the inventive concepts, a mold layer may be formed to include an opening using a mold frame without using an additional process. Thus, the fabricating processes may be simplified.

While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A semiconductor package comprising:
at least one semiconductor chip mounted on a package substrate; and
a mold layer covering the at least one semiconductor chip, wherein the mold layer exposes a portion of a top surface of an uppermost semiconductor chip of the at least one semiconductor chip.

2. The semiconductor package of claim 1, wherein the exposed portion of the top surface of the uppermost semiconductor chip corresponds to a central portion of the top surface of the uppermost semiconductor chip.

3. The semiconductor package of claim 1, wherein the exposed portion of the top surface of the uppermost semiconductor chip corresponds to upper vertexes of the uppermost semiconductor chip.

4. The semiconductor package of claim 1, wherein a top surface of the mold layer is curved.

5. The semiconductor package of claim 4, further comprising:
a thermal boundary material layer and a heat dissipation member stacked on the mold layer.

6. The semiconductor package of claim 5, wherein a thickness of the thermal boundary material layer is varied according to a position of a corresponding portion of the thermal boundary material layer on the semiconductor chip.

7. The semiconductor package of claim 1, wherein the package substrate comprises upper interconnections and lower interconnections, wherein the upper interconnections is higher than the lower interconnections within the package substrate, and
wherein a volume of the upper interconnections is different from a volume of the lower interconnections.

8. The semiconductor package of claim 7, wherein a thickness of the upper interconnections are different from a thickness of the lower interconnections.

9. The semiconductor package of claim 7, wherein an area of the upper interconnections are different from an area of the lower interconnections.

10. The semiconductor package of claim 1, wherein one of the at least one semiconductor chip includes a hot spot region, and
wherein the exposed portion of the top surface of the uppermost semiconductor chip overlaps the hot spot region.

11. The semiconductor package of claim 1, wherein the at least one semiconductor chip includes an interlayer insulating layer having a tensile stress, and
wherein the exposed portion of the top surface of the uppermost semiconductor chip corresponds to a central portion of the top surface of the uppermost semiconductor chip.

12. The semiconductor package of claim 1, wherein the at least one semiconductor chip includes an interlayer insulating layer having a compressive stress, and
wherein the exposed portion of the uppermost semiconductor chip corresponds to upper vertexes of the uppermost semiconductor chip.

13. A method of fabricating a semiconductor package, the method comprising:
mounting at least one semiconductor chip on a package substrate;
covering the at least one semiconductor chip and the package substrate with a mold frame to form an inner space defined by the mold frame, the at least one semiconductor chip and the package substrate,
supplying a mold resin solution into the inner space; and
hardening the mold resin solution to form a mold layer,
wherein the package substrate and the semiconductor chip are curved before the supplying of the mold resin solution.

14. The method of claim 13, wherein the package substrate includes upper interconnections and lower interconnections, and wherein a volume of the upper interconnections is different from a volume of the lower interconnections

15. The method of claim 14, wherein if the volume of the upper interconnections is greater than the volume of the lower interconnections, the package substrate becomes convex, and wherein the mold frame is in contact with a central portion of a top surface of the uppermost semiconductor chip and the mold layer does not cover the central portion.

16. The method of claim 14, wherein if the volume of the lower interconnections is greater than the volume of the upper interconnections, the package substrate becomes concave, and wherein the mold frame is in contact with vertexes of the mold layer.

17. The method of claim 13, wherein the mounting of the at least one semiconductor chip comprises heating the package substrate to a predetermined temperature to cause the package substrate to be curved.

18. The method of claim 14, wherein the at least one semiconductor chip comprises a plurality of stacked interlayer insulating layers having a residual stress which determines a warpage degree of the at least one semiconductor chip.

19. The method of claim 13, further comprising:
performing a singulation process to separate individual semiconductor packages from each other after the mold layer is formed,
wherein, after the singulation process, cooling the package substrate and the semiconductor chip to a room temperature to cause the package substrate and the semiconductor chip to become substantially flat, thereby causing the mold layer to have a curved top surface.

20. The method of claim 13, wherein the mold frame includes a protrusion contacting a top surface of the semiconductor chip.
